(19) United States
(12) Patent Application Publication
(10) Pub. No.: US 2013/0068281 A1
(43) Pub. Date: Mar. 21, 2013

(54) Offset light concentrating

(71) Applicant: Stephan R. Clark, Albany, OR (US)

(72) Inventor: Stephan R. Clark, Albany, OR (US)

(21) Appl. No.: 13/236,426

(22) Filed: Sep. 19, 2011

(51) Int. Cl. H01L 31/052; H01L 31/18

(52) U.S. Cl. 136/246; 29/890.033

(57) ABSTRACT

Offset light concentrating is disclosed. An example method includes providing a parabolic optic having an offset reflective surface for incident light. The method also includes offsetting a photovoltaic device from a path of the incident light. The method also includes concentrating light from the reflective surface of the parabolic optic on the photovoltaic device.

### BACKGROUND

Photovoltaic devices for converting the sun's energy to electrical energy can be used as a supplemental (or even primary) power source. The deployment of photovoltaic devices for commercial and residential electricity consumers is continuing to increase. Due to conversion efficiencies, however, photovoltaic devices often have a large “footprint” and consume valuable “real estate,” meaning that photovoltaic devices are often large in size and can take up substantial space on rooftops and/or at other installations. Therefore, recent development efforts have turned to concentrating photovoltaic devices, which use optics (e.g., mirrors) to focus the sun's energy onto smaller photovoltaic substrates to help reduce overall system cost while increasing system efficiency.

Concentrating optics are typically divided into two groups, one of the reflecting type and the other the refracting type. While concentrating reflective optics (e.g., mirrors) are commonplace, the incident light may be reflected back at the same angle as the incident light, and therefore are difficult to use with photovoltaic cells for high efficiency energy conversion. As a result, reflective concentrator systems typically exhibit light collection loss due to obscuration or unused area due to redirection.

The second type of concentrator is refractive (i.e., optics which bend the light waves). Refractive optics are often variable width and thus can be heavy. A type of refractive optics known as the Fresnel lens has a faceted optical surface that steers the light waves to a focal point. The facets include varying degrees of tilt configured to bend or refract incident light. The facets are such that the lens can be made to have a uniform thickness, enabling a thinner and more lightweight lens. But Fresnel lenses tend to scatter more light than reflective optics, reducing the incident light that can be focused on the photovoltaic device. In addition, the Fresnel lens is complicated and expensive to manufacture.

### BRIEF DESCRIPTION OF THE DRAWINGS

FIG. 1a is a perspective view of an example photovoltaic panel.

FIG. 1b is a perspective view of a portion of the photovoltaic panel shown in FIG. 1a.

FIG. 1c shows a second row of concentrators in “ghost” outline as the optics may be positioned behind a first row of optics to form a “nested” configuration.

FIGS. 2a-b are simplified side views of the photovoltaic panel illustrating (a) reflected light in the same direction as incident light, and (b) reflected light onto an offset photovoltaic substrate.

FIG. 3 is a perspective view of an example photovoltaic device which may be implemented in the photovoltaic panel shown in FIGS. 1a-b.

FIG. 4a is a perspective view of an example optics base material which may be used to make the optics.

FIG. 4b illustrates selection of the optics from the optics base material shown in FIG. 4a.

FIG. 4c is a perspective view of the optics removed from the optics base material shown in FIG. 4a.

FIGS. 5a-c illustrate assembly of example photovoltaic arrays to form the portion of the photovoltaic panel shown in FIGS. 1a-b.

FIGS. 6a-b illustrates example efficient light collection.

### DETAILED DESCRIPTION

Of the two concentrator types reflective tend to be simpler to manufacture and cost less. These may be used with simpler optical coatings that further increase collection efficiency. By removing obscuration or dead space where no light is collected, then the reflective type concentrator can be used at high efficiency and for a low cost. The reflective optics disclosed herein address these issues, and thus can be implemented in concentrating photovoltaic systems with a high collection efficiency

An example photovoltaic system described herein may include a photovoltaic substrate offset from a path of incident light. A parabolic optic may be arranged adjacent the photovoltaic substrate, without blocking incident light. A two dimensional reflective surface of the parabolic optic reflects incident light and thus concentrates sunlight on the photovoltaic device. Accordingly, the reflective optics described herein are relatively simple to manufacture (e.g., compared to the Fresnel lens), can be manufactured at relatively low cost, and provide two dimensional concentration of sunlight without obscuring the incident light.

Although described herein with reference to photovoltaic systems, and more particularly, with reference to concentrating photovoltaic systems, the devices and methods may have application in other fields in which reflecting and/or focusing or concentrating light waves is desired.

Before continuing, it is noted that as used herein, the terms “includes” and “including” mean, but is not limited to, “includes” or “including” and “includes at least” or “including at least.” The term “based on” means “based on” and “based at least in part on.”

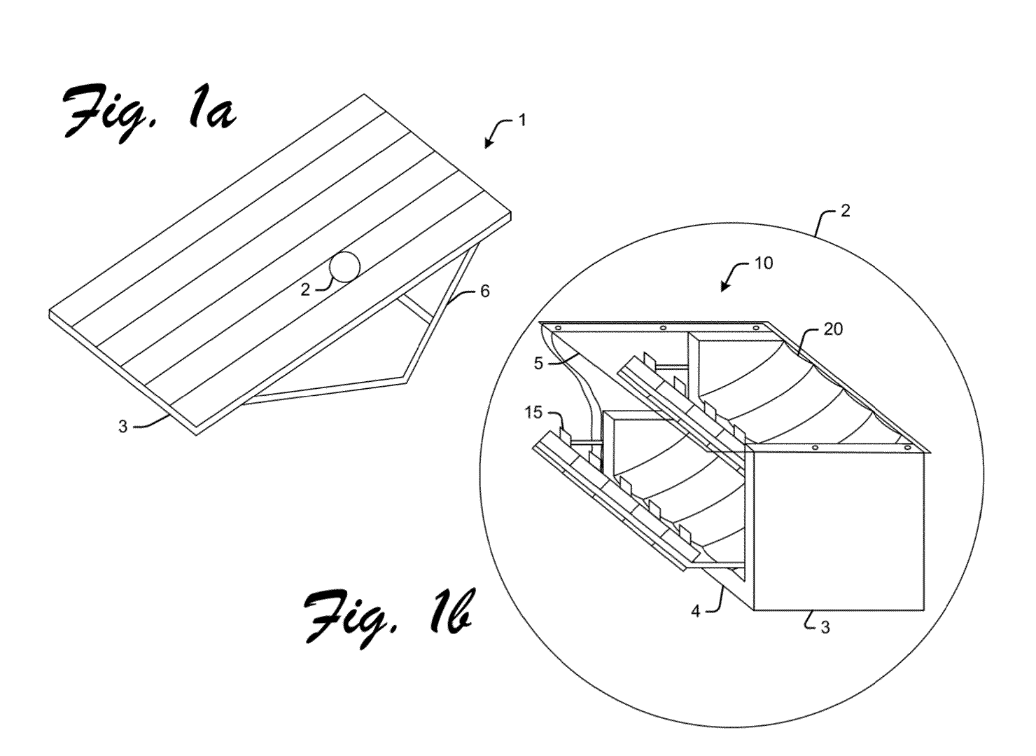

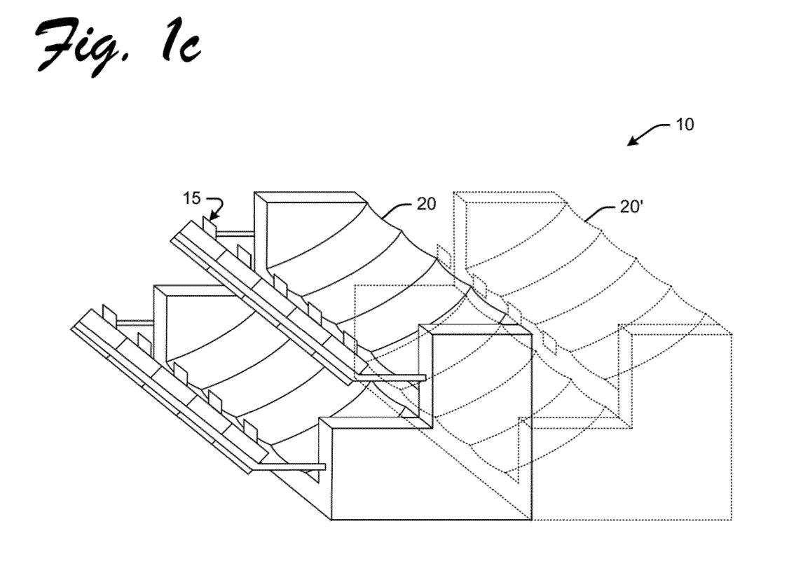

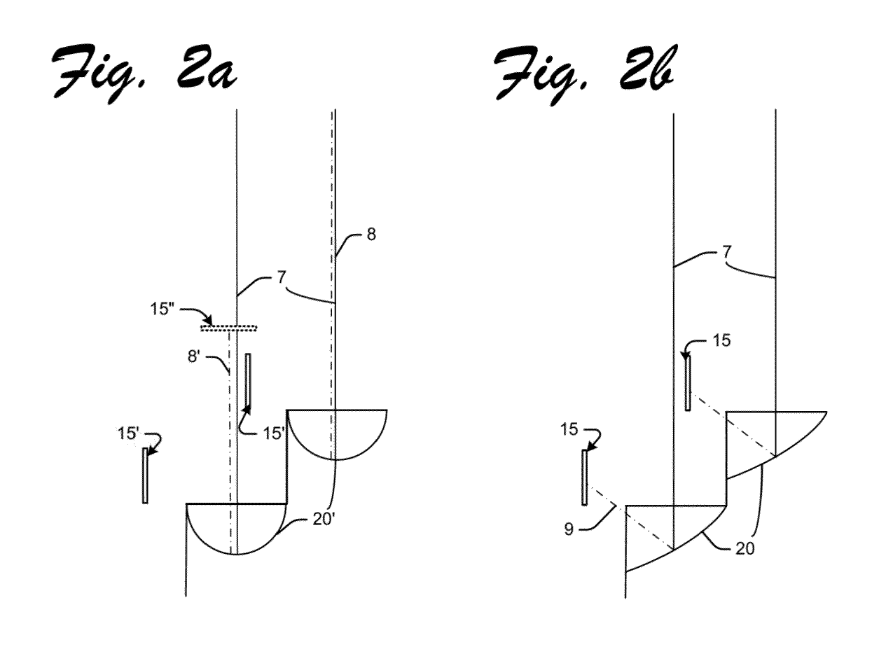

FIG. 1a is a perspective view of an example photovoltaic panel 1. In an example, the photovoltaic panel may implement offset light concentrating. FIG. 1b is a perspective view of a portion 10 of the photovoltaic panel 1 from section 2 shown in FIG. 1a.

The photovoltaic panel 1 may include sidewalls 3 and a base structure 4 forming the structure that is the photovoltaic panel 1 which houses photovoltaic substrate 15. The photovoltaic panel 1 may also include a transparent enclosure 5 (e.g., glass or plastic), which enables sunlight to pass through to optics 20.

The housing, including sidewalls 3, a base structure 4, and transparent enclosure 5, serves to protect the optics 20 and photovoltaic substrate 15 from harsh environmental conditions where the photovoltaic panel 1 may be installed. Photovoltaic panels 1 by their very nature are installed in sunlight, which means the photovoltaic panels 1 are typically installed outdoors and can be subject to extreme temperature fluctuations, wind, and moisture. The housing helps reduce or prevent damage to the internal components. The housing also protects electrical connections and internal wiring which deliver electricity generated by the photovoltaic substrate 15.

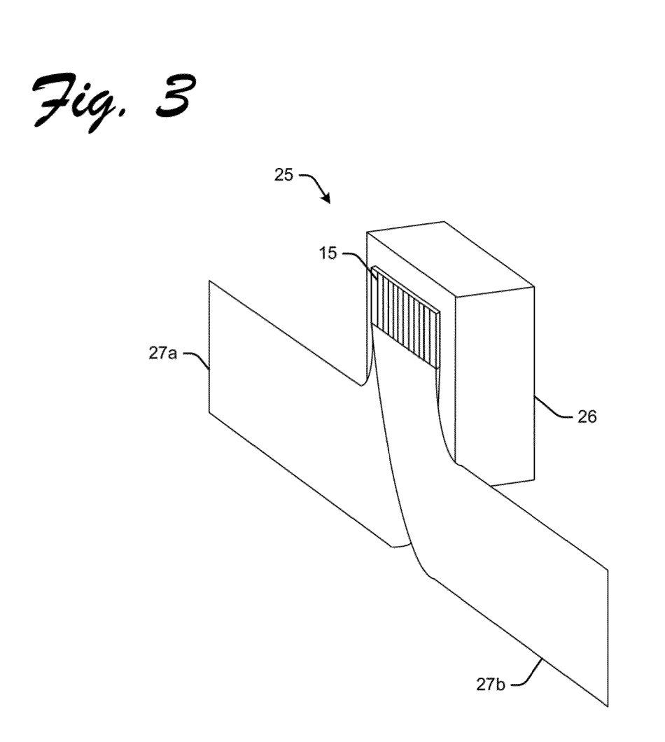

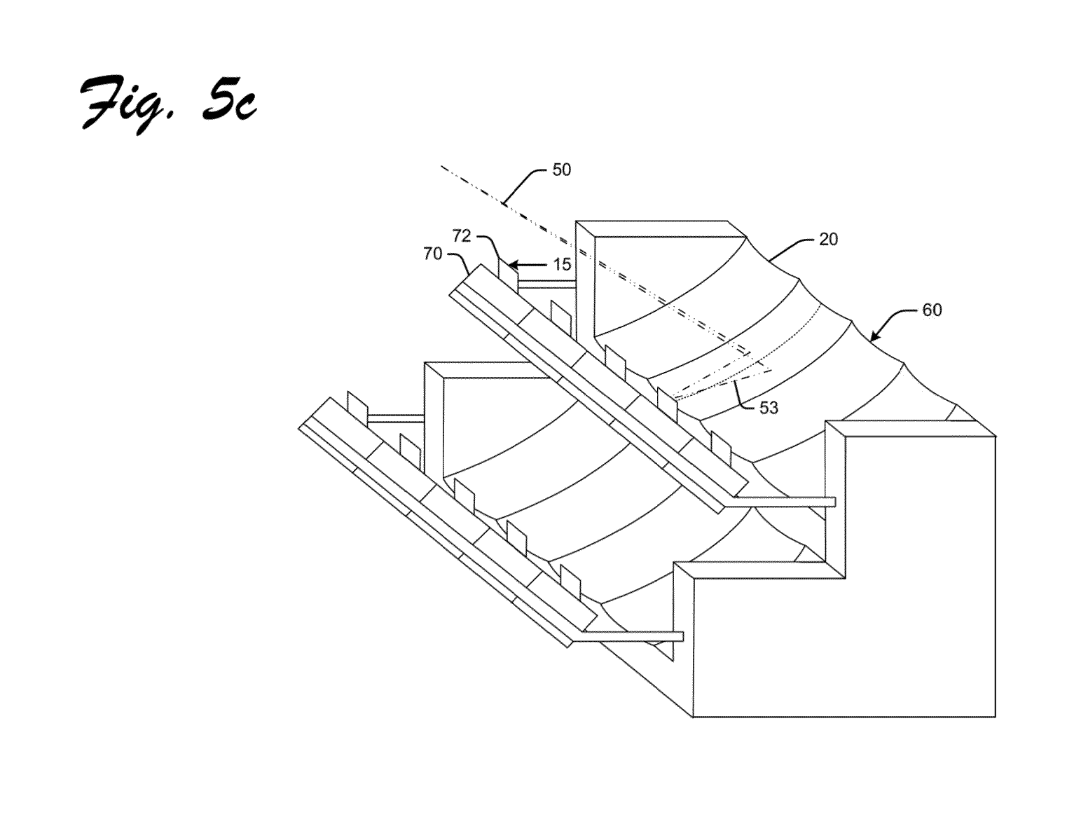

It is noted that the optics 20 are reflective in nature. That is, incident light is reflected from the surface of the optics 20. However, the curved or parabolic structure of the optics 20 is designed to reflect incident light waves onto the photovoltaic substrate 15 (see FIG. 5c), instead of the reflected light being directed back in the same direction as the incident light. Accordingly, the photovoltaic substrate 15 may be offset from the optics 20, enabling light to reach the reflective surface of the optics 20, while minimizing or altogether eliminating obscuring the path of incident light. This is illustrated in FIGS. 2a-b.

FIGS. 2a-b are simplified side views of the photovoltaic panel. In this illustration, FIG. 2a shows a spherically symmetrical optic 20′ as it would reflect light 8′ in the same direction as the incident light 7. Accordingly, the photovoltaic substrate 15′ would need to be positioned in the path of the incident light 7 to collect reflected light 8′, as illustrated by the photovoltaic substrate 15″ in FIG. 2a. However, this configuration would result in the photovoltaic substrate 15′ blocking much of the incident light 7. Instead, the optic 20 has an offset axis, as described in more detail below and illustrated in FIG. 2b, which enables the optic 20 to reflect light 9 onto the photovoltaic substrate 15 offset from the path of incident light 7.

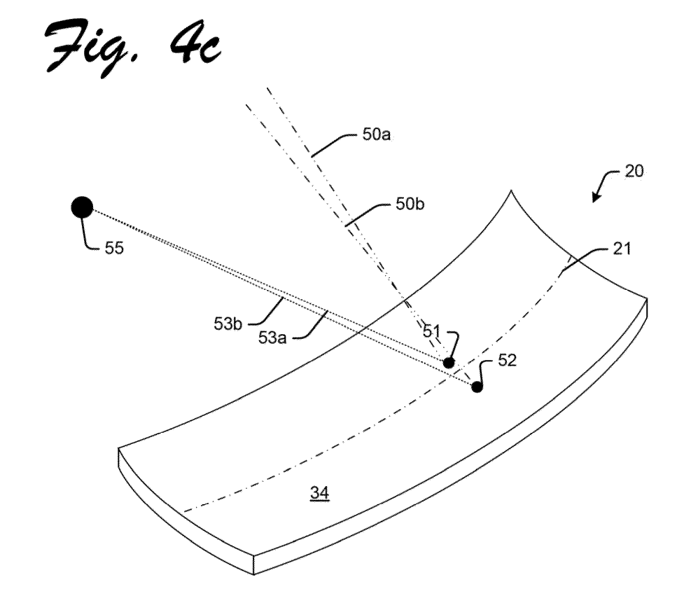

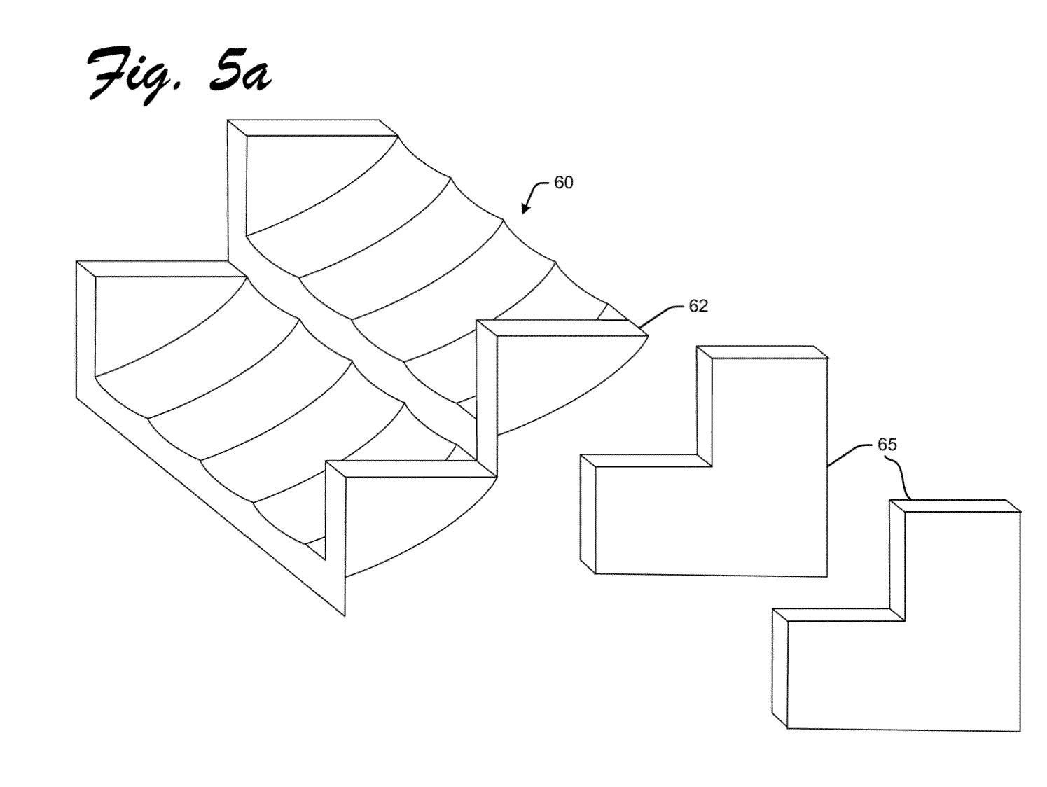

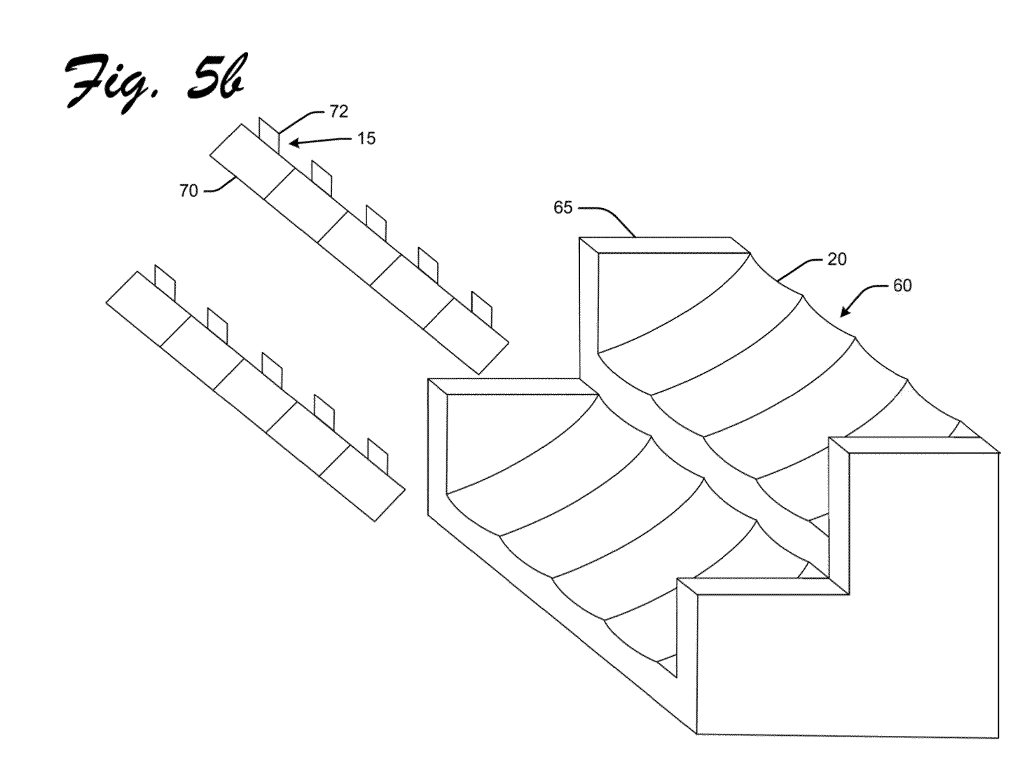

It is further noted that the optics 20 may be at least partially parabolic in shape, giving the optics 20 multi- or at least bi-directional (referred to herein as offset or two dimensional) reflective properties. That is, incident light waves are reflected from each side of a central axis 21 (see FIG. 4c) of the optics 20 and onto the same point or area on the photovoltaic substrate 15. Accordingly, the optics 20 further serve to reduce scatter associated with refractive optics, and concentrate sunlight on the photovoltaic substrate 15. Concentrating sunlight on the photovoltaic substrate increases the so called “energy-from-the-sun” to electricity conversion efficiency of the photovoltaic panel 1, enabling less photovoltaic substrate to be used for the same energy conversion. The structure also has an offsetting characteristic, enabling “nesting” of the photovoltaic substrates relative to one another.

These characteristics are particularly desirable in the energy production field for reducing the “footprint” or “real estate” of solar installations. These characteristics also reduce the amount of materials needed for manufacture, reduce transportation costs for delivering the manufactured photovoltaic panels 1 to the installation (because the panels can be made smaller), and reduce maintenance costs during operation (because there are fewer components).

Before continuing, it should be noted that the example photovoltaic panel 1 described above is provided for purposes of illustration, and is not intended to be limiting. Other devices, components, and configurations are also contemplated.

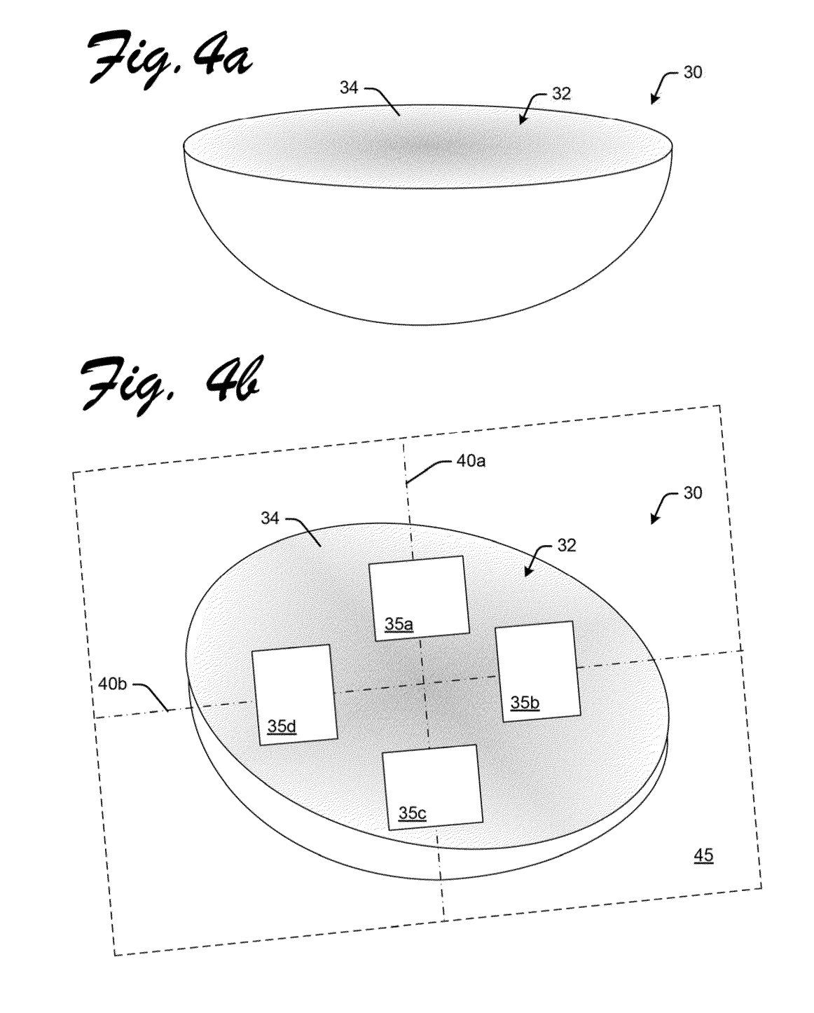

FIG. 3 is a perspective view of an example photovoltaic device 25 which may be implemented in the photovoltaic panel 1 shown in FIGS. 1a-b. The photovoltaic device 25 may include a body 26. The photovoltaic substrate 15 is provided on the body 26. Electrical leads 27a-b are shown attached to the photovoltaic substrate 15. Electrical leads 27a-b may be used to deliver electrical energy generated by the photovoltaic substrate 15 to a storage device (e.g., battery), transmission line (e.g., an electric grid), or end-use (e.g., operating an electrical device).

The body 26 may also include a heat dissipating device (not shown), such as but not limited to, a heat pipe or other heat dissipating structure. It is noted that the heat pipe may be connected to an external heat sink. In an example, the base structure 4 (FIG. 1b) may also serve as a heat sink. Such a configuration enables the concentrated heat to be spread out and conducted quickly to the bottom of the photovoltaic panel 1 for dissipating to the external environment.

The photovoltaic substrate 15 may be any suitable size. In an example, the photovoltaic substrate is about 3 mm by 10 mm (although the substrate can be scaled based on desired energy output and/or other use). The photovoltaic substrate 15 is positioned on one side of the body 26, and the photovoltaic device 25 is installed so that the photovoltaic substrate 15 faces the optics 20. Accordingly, incident light reflected by the optics 20 is directed onto the surface of the photovoltaic substrate 15.

FIG. 4a is a perspective view of an example optics base material 30 which may be used to make the optics 20. The optics 20 may be manufactured from a semi-spherical optics base material 30. The optics base material 30 may be manufactured from any suitable material such as, but not limited to metal, alloy, plastic, or composite. Interior 32 of the optics base material 30 has a surface 34 which may be reflective. The surface 34 may be made reflective using suitable deposition techniques (e.g., spray deposition, vapor deposition), applied as a lining, polished, or otherwise provided. In another example, the surface 34 may be made reflective after removing the optics 20 from the optics base material 30.

FIG. 4b illustrates selection of the optics 20 from the optics base material 30 shown in FIG. 4a. In an example, the optics base material 30 may be quartered (e.g., as illustrated by lines 40a-b each bisecting planar space 45. However, the optics base material 30 may be subdivided in other manners as well, including halved, and so forth. The specific subdividing may vary based on the size of the optics base material 30 and other design considerations. For example, only a single portion may be removed from the optics base material 30 to form the optics 20 based on quality control measures.

In an example, a rectangle 35 (35a-d are shown in FIG. 4b) is superimposed in planar space 45 above the optics base material 30. The rectangle 35 is oriented symmetrically across the lines 40a-b, and offset from the center of the optics base material 30. The rectangle formed in planar space 45 can then be projected down onto the curved interior surface 34 of the optics base material 30. For example, the rectangle 35 may be light generated (e.g., using a laser beam), so that the rectangle 35 can be projected down onto the curved interior surface 34 of the optics base material 30.

It is noted that other selection methods may also be utilized. The rectangle 35 may be positioned in any desired location in planar space 45 to achieve the desired reflective effect. The shape may also be selected directly on the interior surface 34 of the optics base material 30, and need not be established in planar space 45. In addition, the rectangle 35 may be a square or any other desired geometry (e.g., circular, hexagonal). It is also noted that the

A portion of the optics base material 30 may then be removed, e.g., based on the projection of the rectangle 35 onto the interior surface 34 of the optics base material 30. Removing the optics base material 30 may be by any suitable cutting method, including using laser beam cutting techniques.

FIG. 4c is a perspective view of the optic 20 removed from the optics base material 30 shown in FIG. 4a. In this example, the optic 20 corresponds to the rectangle 35a established in planar space 45 and projected onto the interior surface 34 of the optics base material 30. It can be seen that the resulting optic 20 is parabolic in shape, and includes a portion of the surface 34 of the interior 32 of the optics base material 30.

In addition, the optic 20 includes a central axis 21 which enables a two dimensional reflective surface. That is, incident light waves 50a-b to corresponding points 51 and 52 on each side of the axis 21, respectively, result in reflected light waves 53a-b from each side of the axis 21 being focused onto a single point area 55 on the photovoltaic substrate 15 (not shown in FIG. 4c). Accordingly, the light energy is concentrated (i.e., the energy of incident light is increased at point 55).

It is noted that the manufacturing method described above is an example manufacturing method. Moreover, this illustration is intended to show that the system is using an off-axis section of a spherically symmetric base optic, and is not intended to be limiting to a method of manufacture. Indeed, other methods of manufacture may include a thermo-foam technique for producing the optic. That is, the section under the rectangle 35 is replicated on a tool die and used for a mold for a heat plastic sheet. These may be produced in arrays of optics, as shown in the figure, so the optics will be right next to each other, without any gaps, to provide a maximum light collection area.

FIGS. 5a-c illustrate assembly of example photovoltaic arrays to form the portion 2 of the photovoltaic panel 1 shown in FIGS. 1a-b. In FIG. 5a, a support molding 60 is shown as it may be made by extrusion or other manufacturing techniques. Support molding 60 includes beds 61 for the optics 20. The beds 61 may be molded to substantially conform to the bottom side of the optics 20. Support elbows 62 are also shown for mounting the support molding 60 to support structures 65.

In FIG. 5b, the support molding 60 is mounted to the support structures 65, and the optics 20 have been positioned in the beds 61 to form arrays. Chip structures 70 are shown which may be used to support the photovoltaic substrates 15, and associated electrical routing and heat removal path. In an example, the photovoltaic substrates 15 may be mounted to posts 72.

In FIG. 5c, the chip structures 70 are shown mounted to the support structures 65. After assembly, each photovoltaic substrate 15 on post 72 aligns with the central axis of the optics 20 (e.g., central axis 21 shown in FIG. 4c) to form a photovoltaic array. It can be seen in this example that the optics 20 (and corresponding photovoltaic substrates 15) can be arranged in arrays and rows, and that the rows can be stacked and nested relative to one another. Any number of rows, and stacks of rows may be provided to form any desired depth and width comprising the photovoltaic panel 1 shown in FIG. 1a. By way of illustration, a second row of concentrators is shown in “ghost” outline in FIG. 1c as the optics 20′ may be positioned behind a first row of optics 20, thus forming a “nested” configuration.

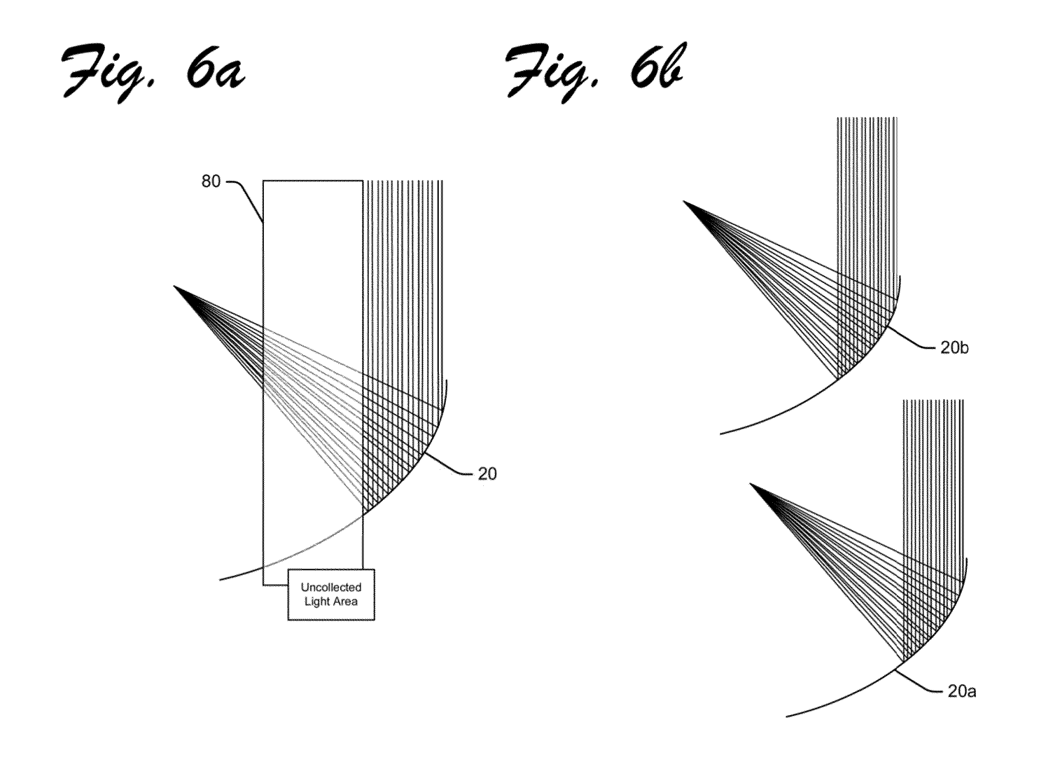

For one row of optics 20 (and photovoltaic substrate 15), there is a space 80 where no light is collected by the photovoltaic substrate 15, as shown in FIG. 6a. Placing a second row of optics in space 80 so there is a two row combination as shown in the figure as 20a and 20b (and corresponding photovoltaic substrates) in the section 80 enables more efficient light collection when stacking rows of optics for a large area of light collection, as shown in FIG. 6b. That is, there is more power for a given full module of concentrated solar collectors. In an example, the second row is a copy of the first row positioned at lower than the first to allow the light from the row to go to the first photovoltaic substrate 15 without being blocked, and allowing the other light that would have been missed in space 80 to be collected by the bottom row of second parabolic sections. In addition, the photovoltaic substrates 15 can be placed underneath the next double row set of optics, and thus do not block light as shown in FIG. 1c (note the dashed outline of a second two row optic where the photovoltaic substrates 15 are nestled under the first set of rows.

This architecture reduces unused apertures for the incident light that is coming from the sun. Thus, almost all of the area shown through the cover 5 may be used to collect light and concentrate the light on the photovoltaic substrate 15. This architecture also provides a simple two dimensional concentration optic that is low cost and readily manufactured using conventional techniques. The two dimensional concentration reduces the chip area needed to meet desired power output, and thus also serves to reduce the system cost.

The architecture also compensates for some assembly errors and optic fabrication errors. That is, as the optics 20 are all aligned in the same direction, the photovoltaic panel 1 can be tilted, rotated, and/or moved to realign the incident light of the sun. If the optics had crossed foci, such realignment would necessarily result in misaligning half of the array in order to adjust the other side.

It is noted that the examples shown and described are provided for purposes of illustration and are not intended to be limiting. Still other examples are also contemplated.

1. A device comprising:
a parabolic optic having an offset reflective surface; and
a photovoltaic device offset from an incident light path, wherein the reflective surface of the parabolic optic concentrates light on the photovoltaic device.

2. The device of claim 1, further comprising a frame assembly supporting the parabolic optic.

3. The device of claim 1, further comprising a plurality of parabolic optics configured in a stacked arrangement without obscuring the incident light path.

4. The device of claim 3, wherein all of the plurality of parabolic optics are aligned in substantially the same direction.

5. The device of claim 1, further comprising two arrays of parabolic optics.

6. The device of claim 5, wherein one of the two arrays of parabolic optics is nested relative to the other array.

7. The device of claim 1, wherein the two arrays of parabolic optics are arranged one below and offset from the other.

8. The device of claim 1, wherein the parabolic optic is thermoformed.

9. The device of claim 1, wherein the parabolic optic is an off-axis section from a spherically symmetric optic.

10. The device of claim 1, wherein a focus point of the parabolic optic is offset to a side of the incident lightpath.

11. A photovoltaic system, comprising:
a photovoltaic substrate offset from a path of incident light;
a parabolic optic arranged adjacent the photovoltaic substrate; and
an offset reflective surface of the parabolic optic to concentrate the incident light on the photovoltaic device.

12. The system of claim 11, wherein the parabolic optic is removed from an off-axis portion of a spherically symmetric optic.

13. The system of claim 11, wherein the parabolic optic is part of an array of parabolic optics.

14. The system of claim 11, wherein the array of parabolic optics is stacked relative to another array of parabolic optics without blocking the path of incident light.

15. The system of claim 11, wherein the array of parabolic optics is arranged below and offset from another array of parabolic optics without blocking the path of incident light.

16. A method comprising:
providing a parabolic optic having on offset reflective surface for incident light;
offsetting a photovoltaic device from a path of the incident light; and
concentrating light from the reflective surface of the parabolic optic on the photovoltaic device.

17. The method of claim 16, further comprising supporting the parabolic optic in a stacked arrangement of parabolic optics.

18. The method of claim 16, further comprising aligning the parabolic optic in substantially the same direction as a plurality of parabolic optics.

19. The method of claim 16, further comprising concentrating the incident light on the photovoltaic device.

20. The method of claim 16, further comprising routing an electrical connection and a heat path for the photovoltaic device without obscuring the path of incident and a path of the reflected light.
